(19) United States
(12) Patent Application Publication
(10) Pub. No.: US 2006/0172538 A1
(43) Pub. Date: Aug. 3, 2006

(54) Wet etching the edge and bevel of a silicon wafer

(76) Inventors: Herman Itzkowitz, Bala Cynwyd, PA (US); John Taddei, Breinigsville, PA (US)

Correspondence Address: JOHN W. GOLDSCHMIDT, JR. ESQUIRE;DILWORTH PAXON LLP, 3200 MELLON BANK CENTER, 1735 MARKET STREET, PHILADELPHIA, PA, 19103, US

(21) Appl. No.: 11/294,644

(22) Filed: Dec. 5, 2005

Related U.S. Application Data
(60) Provisional application No. 60/633,061, filed on Dec. 3, 2004.

(51) Int. Cl. H01L 21/302

(52) U.S. Cl. 438/689; 438/735; 438/745

(57) ABSTRACT

A method and apparatus to selectively etch layers of various materials from the edge and bevel areas of the active side of a silicon wafer, as well as from the inactive side of a wafer are disclosed. The width of the etched edge generally varies from about 0.5 to about 5 mm and however the etching may be determined by the geometry of the supporting chuck and the surface tension of the etching medium.

### CROSS REFERENCE TO RELATED APPLICATION

This application claims priority to U.S. provisional patent application Ser. No. 60/633,061, filed Dec. 3, 2004.

### FIELD OF THE INVENTION

This invention generally relates to the manufacture of devices employing wet etching processes. More specifically, this invention relates to: a method and apparatus for removing and reducing contaminants present in, or introduced during, the wet etching process, wherein the devices produced by such processes are produced without a substantial decrease in performance of the resulting device.

### BACKGROUND OF THE INVENTION

The continued decrease in the sizes of devices being produced from silicon or other substrate wafers in wet etching processes has made the wafers more vulnerable to contamination from particles and debris. Semiconductor manufactures utilize a number of cleaning procedures throughout the process of wafer manufacture to remove undesirable debris from the wafer surface.

Loss analysis studies have indicated that a significant source of debris that leads to a reduction in wafer yield is the presence of undesirable substances on the wafer backside and on the outer several millimeters of the feature, active or top side or surface of the wafer. These debris may comprise both contamination from foreign particles and desired and/or undesired materials and/or layers which are present in, or introduced during, the wafer manufacturing process. In one instance, desired materials may be deposited or collected at or near this edge of the wafer without the benefit of tight control due to the location at the edge of the wafer. An etching process that removes all materials on the wafer backside and on the feature side along the edge of the wafer without adversely impacting the ultimate performance of the devices being produced will generally remove the source of contamination, and thus increase wafer yield.

These materials may be removed from the backside and outer feature side edges through the application of a barrier layer, followed by a thin layer of copper applied by a physical vapor deposition (PVD) process, followed by a thicker layer of copper using electroplating. However, poor quality at the edge of the wafer may result in the thin layer of copper flaking off causing contamination in subsequent steps of the etching process, or diffusing into the silicon or substrate material due to problems with the barrier layer of the substrate. Thus, the need exists for a process and apparatus to enable excess copper, and other undesirable deposits on the surface of the wafer, to be removed during the etching process.

### SUMMARY OF THE INVENTION

This problem may be solved by etching away the copper layer, or other undesirable contaminants, at the edge of the wafer to a distance where all the layers being deposited on the surface of the wafer are applied to the wafer properly without adversely impacting the performance of the device produced by the etching process.

Layers that often need to be removed from the edge or other areas of the wafer are: copper, aluminum, silicon-oxide and silicon-nitrite, although it may be desirable to remove other materials from the wafer. The distance from the edge should be precisely controlled to insure that the defective areas are substantially completely removed and that there is no substantial undesired etching in the active areas of the device produced from the wafer being etched.

In one embodiment, this invention generally comprises a method and apparatus for removing unwanted material from the edge and bevel areas of a wafer, by:
placing the wafer (having a feature side and non-feature side), feature-side down on a cushion of gas above a spin chuck, wherein the chuck has a bevel flow ring;
vertically setting the size of the flow ring;
rotating the spin chuck and supported wafer at a rate in order to create a centrifugal force affecting any fluid applied to the wafer; and
applying a chemical etching fluid to the non-feature-side of the wafer, in amount sufficient to fill a gap between the wafer and the flow ring as the etching fluid flows over the edge of the wafer onto the flow ring, and into a space between the wafer and the flow ring, wherein the feature side of the wafer is substantially protected from exposure to the etching fluid and the areas etched are determined by an overlap between the wafer and the ring.

### BRIEF DESCRIPTION OF THE DRAWINGS

Understanding of the present invention will be facilitated by consideration of the following detailed description of the embodiments of the present invention taken in conjunction with the accompanying drawings, in which like numerals refer to like parts, and wherein:

FIG. 1 shows a plan view of the active side of a wafer produced by this invention.

FIG. 2 is the cross section of one embodiment of the bevel etch spin chuck of this invention.

FIG. 3 shows a cross sectional detail of the spin chuck of FIG. 2.

FIG. 4 depicts a cross sectional view of the wafer of FIG. 1, and an exploded view of the edge of the wafer of FIG. 4.

### DETAILED DESCRIPTION OF THE INVENTION

It is to be understood that the figures and descriptions of the present invention have been simplified to illustrate elements that are relevant for a clear understanding of the present invention, while eliminating, for the purposes of clarity, many other elements which may be found in the present invention. Those of ordinary skill in the pertinent art will recognize that other elements are desirable and/or required in order to implement the present invention. However, because such elements are well known in the art, and because such elements do not facilitate a better understanding of the present invention, a discussion of such elements is not provided herein.

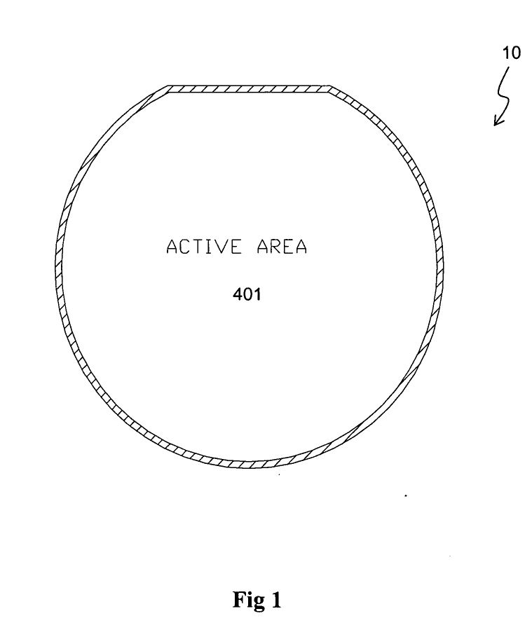

Turning now to FIGS. 1 and 4, FIG. 1 shows a plan view of active side 401 of wafer 10, which during at least one embodiment of the bevel etching process of this invention is facing downward. Numeral 401 depicts active protected area of wafer 10 which is not etched. Referring now to FIG. 4, areas 402, 403 and 404 are the areas where etching takes place, while area 401 is the active feature area of wafer 10 which is not etched.

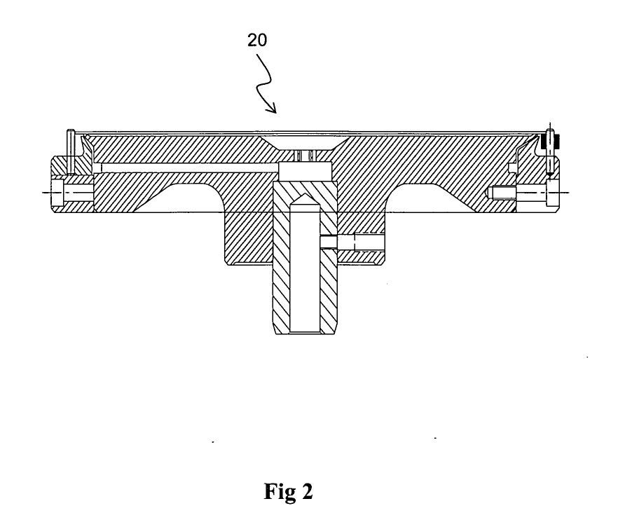

FIG. 2 depicts the cross section of a bevel etch spin chuck 20. Chemical etching fluid is dispensed above wafer 10 and as spin chuck 20 rotates, the etching fluid flows to the outside periphery or edge of wafer 10.

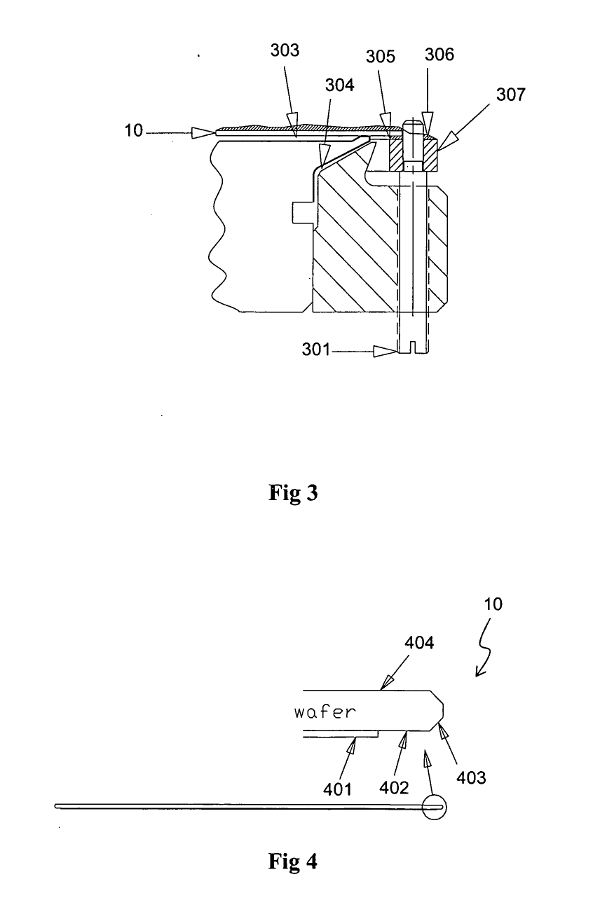

FIG. 3 shows a detail of the cross section of spin chuck 20 of FIG. 2. Wafer 10 is placed on chuck 20 with the active area 401 facing down and protected by a continuous flow of nitrogen or other gas 303 which creates a cushion between wafer 10 and the chuck 20. The gas is fed through channel 304 to create gas cushion 303. An outside ring 307 can be adjusted in the vertical orientation by adjusting screw 301. The adjustment is made so there is a gap 305 between ring 307 and active area 401 of wafer 10. The fluid dispensed above wafer 10 fills gap 305, with the excess overflowing into area 306.

Wafer 10 is processed feature side 401 down on a rotating chuck 20. Wafer 10 floats on nitrogen or other gas cushion 303 that prevents contact with chuck 20 and prevents chemical etching fluid or other chemistry from reaching active area 401 of wafer 10. Chuck 20 contains bevel flow ring 307 that can be set to a fixed gap 305 between flow ring 307 and wafer 10. Chemical etching fluid or other chemistry is dispensed from above on the backside or non-active area 404 of wafer 10. Due to the centrifugal force, the chemistry flows to the outer edge of wafer 10. The chemistry then flows off wafer 10 edge and down onto flow ring 307. The chemistry fills bevel flow ring 307 and contacts the outer edge (typically by about several millimeters) on feature side 401 of wafer 10. With a relatively slow rotational velocity (typically between about 50 rpm and about 1200 rpm), chemistry is held by surface tension in gap 305 between wafer 10 and flow ring 307. The etch distance from the edge of wafer 10 is determined by the distance that flow ring 307 overlaps with wafer 10. The fluid in gap 305 also acts as a seal and prevents fluid from splashing onto active area 401 of wafer 10.

Once the etching process is complete, the rotational velocity is increased (typically from between about 500 rpm to about 2000 rpm) to force the chemistry out of gap 305.

If multiple layers are present, several chemistries may be required to etch down to the desired surfaces of wafer 10. When the etching process is complete, wafer 10 may be rinsed and spun dry.

In the instant embodiment, gap 305 varies between about 0.001″ and about 0.015″ depending on the viscosity and surface tension of the etching fluid. Also in this embodiment, wafer 10 and flow ring 307 may overlap by about 0.5 to about 5 mm which determines the distance from the edge of the etched area of wafer 10.

The disclosure herein is directed to certain features of the elements and methods of the invention disclosed as well as others that will be apparent to those skilled in the art in light of the disclosure herein. Thus, it is intended that the present invention covers all such modifications and variations of this invention, provided that those modifications come within the scope of the claims granted herein and the equivalents thereof.

What is claimed is:

1. A method for removing unwanted material from edge and bevel areas of a wafer having a feature and non-feature surfaces, said method comprising:
placing the wafer, feature-side down, on a cushion of continuously flowing gas to form a gas cushion above a bevel etch spin chuck, such that the wafer is in close proximity to, but not touching, the spin chuck when rotating, and wherein the chuck further comprises a bevel flow ring that can be vertically adjusted and set to a size permitting a predetermined fixed gap between the flow ring and the feature-side of the wafer when the wafer is placed onto the gas cushion;
vertically setting the size of the flow ring;
rotating the spin chuck and supported wafer at a rate therein creating a centrifugal force affecting any fluid applied to the wafer;
applying a chemical etching fluid to the non-feature-side of the wafer, in amount sufficient to fill the gap between the wafer and the flow ring as the etching fluid flows over the edge of the wafer onto the flow ring, and into the space between the wafer and the flow ring, wherein the feature side of the wafer is protected from exposure to the etching fluid and the areas etched are determined by the overlap between the wafer and the ring.

2. The method of claim 1, further comprising applying at least one chemical etching fluid to a central point on the non-feature-side of the wafer, therein etching substantially the entire non-feature side, bevel area and a defined ring on the feature side of the wafer as determined by the overlap between the wafer and the ring.

3. The method of claim 1, further comprising applying at least one chemical etching fluid to the outer edge of the non-feature-side of the wafer, therein etching the bevel area and a ring on the feature side of the wafer as determined by the overlap between the wafer and the ring, wherein the centrifugal force causes the fluid to move away from the center of the wafer, preventing the etching fluid to contact the central portion of the non-feature side of the wafer.

4. The method of claim 1, further comprising applying at least one chemical etching fluid to a central point on the non-feature-side of the wafer, without the ring overlapping the feature-side of the wafer, therein etching substantially only the non-feature side and a vertical edge of the wafer.

5. The method of claim 1, further comprising applying at least one chemical etching fluid to the outer edge of the non-feature-side of the wafer, without the ring overlapping the feature-side therein etching substantially only a vertical edge of the wafer.

6. The method of claim 1, further comprising repeating the step of applying the chemical etching fluid, wherein the etching fluid used in the repeated step is different from the originally or previously applied etching fluid, therein etching multiple layers of the wafer.

7. The method of claim 1, further comprising increasing the rotational velocity to a speed sufficient to force the etching fluid out of the gap between the flow ring and the bottom of the wafer, therein substantially removing residual etching fluid.

8. The method of claim 1, further comprising rinsing the wafer with a rinsing fluid after the etching process is completed, then spinning the rinsed wafer to dry it.

9. A device for removing unwanted material from an edge and bevel area of a wafer, said device comprising:
a bevel etch spin chuck, over which there is a means to provide a cushion of continuously flowing a gas sufficient to support a wafer placed thereon, wherein the chuck further comprises a bevel flow ring that can be vertically adjusted and set to a size permitting a predetermined fixed gap between the flow ring and the feature-side of the wafer when the wafer is placed onto the gas cushion; and
a means for applying a chemical etching fluid to the non-feature-side of the wafer, in amount sufficient to fill the gap between the wafer and the flow ring as the etching fluid flows over the edge of the wafer onto the flow ring, and into the space between the disc and the flow ring, wherein the feature side of the wafer is therein protected from exposure to the etching fluid and the areas etched are determined by the overlap between the wafer and the ring.

10. The device of claim 9, wherein the means for applying at least one chemical etching fluid directs the fluid to a central point on the non-feature-side of the wafer, such that substantially the entire non-feature side, bevel area and a defined ring on the feature side of the wafer are etched as determined by the overlap between the wafer and the ring.

11. The device of claim 9, wherein the means for applying at least one chemical etching fluid directs the fluid to the outer edge of the non-feature-side of the wafer, such that substantially only the bevel area and a ring on the feature side of the wafer are etched, as determined by the overlap between the wafer and the ring.

12. The device of claim 9, wherein the means for applying at least one chemical etching fluid directs the fluid to a central point on the non-feature-side of the wafer, without the ring overlapping the feature-side of the wafer, such that substantially only the non-feature side and the vertical edge of the wafer are etched.

13. The device of claim 9, wherein the means for applying at least one chemical etching fluid directs the fluid to the outer edge of the non-feature-side of the wafer, without the ring overlapping the feature-side of the wafer, such that substantially only the vertical edge of the wafer is etched.

14. The device of claim 9, wherein a means for applying the chemical etching fluid permits the sequential application of a subsequent etching fluid composition after the etching process is complete using the original or previously applied etching fluid, causing the etching multiple layers of the wafer.

15. A method for removing material from one or more areas of a wafer, said wafer having feature and non-feature surfaces, said method comprising:
placing said wafer on a cushion of gas above a spin chuck, said chuck having a bevel flow ring;
setting a vertical dimension of the flow ring;
rotating the spin chuck and supported wafer to create a centrifugal force affecting any fluid applied to the wafer; and
applying a chemical etching fluid to the non-feature side of said wafer wherein the feature side of said wafer is not substantially exposed to said etching fluid, and said wafer is etched in those areas defined by an overlap between said wafer and said ring.

16. An apparatus for removing material from one or more areas of a wafer, said wafer having feature and non-feature surfaces, said apparatus comprising:
a spin chuck having:
a cushion of gas above said spin chuck; and
an adjustable bevel flow ring;
wherein said spin chuck may rotate while supporting said wafer on said gas cushion to create a centrifugal force affecting any chemical etching fluid applied to said wafer, and wherein the feature surface of said wafer is not substantially exposed to said etching fluid and said wafer is etched in those areas defined by an overlap between said wafer and said ring.

17. A wafer produced by the method of claim 15.
